(19) United States
(12) Patent Application Publication
(10) Pub. No.: US 2022/0028052 A1
(43) Pub. Date: Jan. 27, 2022

(54) APPARATUS AND METHOD FOR GROUPING IMAGE PATTERNS TO DETERMINE WAFER BEHAVIOR IN A PATTERNING PROCESS

(71) Applicant: ASML NETHERLANDS B.V., Veldhoven (NL)

(72) Inventors: Zhiqin LI, Shenzhen, Guangdong (CN); Lei MO, Shenzhen (CN); Youping ZHANG, Cupertino, CA (US)

(73) Assignee: ASML NETHERLANDS B.V., Veldhoven (NL)

(21) Appl. No.: 17/311,422

(22) PCT Filed: Nov. 12, 2019
(86) PCT No.: PCT/EP2019/081002

§ 371 Date: Jun. 7, 2021

Related U.S. Application Data
(60) Provisional application No. 62/779,637, filed on Dec. 14, 2018.

(51) Int. Cl. G06T 7/00

(52) U.S. Cl. CPC G06T 7/0004; G06T 2207/30148; G06T 2207/20081

(57) ABSTRACT

Grouping image patterns to determine wafer behavior in a patterning process with a trained machine learning model is described. The described operations include converting, based on the trained machine learning model, one or more patterning process images including the image patterns into feature vectors. The feature vectors correspond to the image patterns. The described operations include grouping, based on the trained machine learning model, feature vectors with features indicative of image patterns that cause matching wafer and/or wafer defect behavior in the patterning process. The one or more patterning process images include aerial images, resist images, and/or other images. The grouped feature vectors may be used to: detect potential patterning defects on a wafer during a lithography manufacturability check as part of optical proximity correction, adjust a mask layout design, and/or generate a gauge line/defect candidate list, among other uses.

### CROSS-REFERENCE TO RELATED APPLICATIONS

This application claims priority of U.S. application 62/779,637 which was filed on Dec. 14, 2018 and which is incorporated herein in its entirety by reference.

### TECHNICAL FIELD

The description herein relates generally to mask manufacturing and patterning processes. More particularly, the description relates to apparatuses and methods for grouping image patterns that cause matching wafer and/or wafer defect behavior in a patterning process with a trained machine learning model.

### BACKGROUND

A lithographic projection apparatus is a machine that applies a desired pattern onto a target portion of a substrate (e.g., a silicon wafer). A lithographic projection apparatus can be used, for example, in the manufacture of integrated circuits (ICs). In such a case, a patterning device (e.g., a mask) may provide a pattern corresponding to an individual layer of the IC (“design layout”), and this pattern can be transferred onto a target portion of the substrate that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time.

### SUMMARY

According to an embodiment, a method for grouping image patterns to determine wafer behavior in a patterning process with a trained machine learning model is provided. The method comprises converting, based on the trained machine learning model, one or more patterning process images comprising the image patterns into feature vectors. The feature vectors correspond to the image patterns. The method comprises grouping, based on the trained machine learning model, feature vectors with features indicative of image patterns that cause matching wafer behavior in the patterning process.

In an embodiment, the method for grouping image patterns to determine wafer behavior is a method for grouping image patterns to identify potential wafer defects in the patterning process. In an embodiment, method further comprises grouping, based on the trained machine learning model, feature vectors with features indicative of image patterns that cause matching wafer defect behavior in the patterning process.

In an embodiment, the one or more patterning process images comprise aerial images and/or resist images. In an embodiment, the method further comprises using the grouped feature vectors to facilitate detection of potential patterning defects on a wafer during a lithography manufacturability check (LMC).

In an embodiment, the trained machine learning model comprises a first trained machine learning model and a second trained machine learning model. Converting the one or more patterning process images comprising the image patterns into feature vectors is based on the first trained machine learning model. Grouping feature vectors with features indicative of image patterns that cause matching wafer or wafer defect behavior is based on the second trained machine learning model.

In an embodiment, the first machine learning model is an image encoder trained to: extract features from aerial images and/or resist images indicative of: short range aerial and/or resist image pattern configurations; and long-range pattern structures that influence the wafer or wafer defect behavior; and encode the extracted features into the feature vectors.

In an embodiment, the first machine learning model comprises a loss function.

In an embodiment, grouping the feature vectors with features indicative of image patterns that cause matching wafer or wafer defect behavior based on the second machine learning model comprises: grouping the feature vectors into first groups based on the features indicative of the short range aerial and/or resist image pattern configurations, and grouping the feature vectors into second groups based on the first groups and the long range pattern structures that influence the wafer or wafer defect behavior, such that the second groups comprise the groups of feature vectors with the features indicative of image patterns that cause the matching wafer or wafer defect behavior in the patterning process.

In an embodiment, the method further comprises training the first machine learning model with simulated aerial images and/or resist images.

In an embodiment, the method further comprises iteratively re-training the first machine learning model based on output from the first machine learning model and additional simulated aerial and/or resist images.

In an embodiment, the first machine learning model comprises the loss function, and iteratively re-training the first machine learning model based on the output from the first machine learning model and the additional simulated aerial and/or resist images comprises adjusting the loss function.

In an embodiment, the method further comprises training the second machine learning model with labeled wafer defects from a wafer verification process.

In an embodiment, a given labeled wafer defect includes information related to: short range aerial and/or resist image pattern configurations associated with the given labeled wafer defect, long range pattern structures associated with the given labeled wafer defect, behavior of the given labeled wafer defect in the patterning process, coordinates of a location of the given labeled wafer defect and a critical dimension at that location, an indication of whether the given labeled wafer defect is a real defect or not, and/or information related to an exposure of an image of the given labeled wafer defect at the location.

In an embodiment, the information related to the short-range aerial and/or resist image pattern configurations associated with the given labeled wafer defect, and the long-range pattern structures associated with the given labeled wafer defect, are related to a probability of whether the given labeled wafer defect is real or not.

In an embodiment, the method further comprises iteratively re-training the second machine learning model based on output from the second machine learning model, the given labeled wafer defect, and additional labeled wafer defects from the wafer verification process.

In an embodiment, the feature vectors describe the image patterns and include features related to LMC model terms and/or imaging conditions for the one or more patterning process images.

In an embodiment, the method comprises the grouping of the feature vectors into first groups based on the features indicative of the short-range aerial and/or resist image pattern configurations, and wherein the features indicative of the short-range aerial and/or resist image pattern configurations include the features related to LMC model terms and/or imaging conditions for the one or more patterning process images.

In an embodiment, the method is used during an optical proximity correction (OPC) portion of the patterning process.

In an embodiment, the method further comprises identifying groups of potential wafer defects that have matching wafer defect behavior in the patterning process based on the grouping of the feature vectors with the features indicative of image patterns that cause the matching wafer defect behavior in the patterning process.

In an embodiment, the method further comprises adjusting a mask layout design of a mask of the patterning process based on the groups of potential wafer defects that have the matching wafer defect behavior in the patterning process. In an embodiment, the method is used to generate a gauge line/defect candidate list to enhance accuracy and efficiency of wafer verification.

In an embodiment, the method further comprises predicting, based on the trained machine learning model, a ranking indicator to indicate a relative severity of individual potential wafer defects, the ranking indicator being a measure of how likely a potential wafer defect is to transform into one or more physical wafer defects.

According to another embodiment, a computer program product is provided. The computer program product comprises a non-transitory computer readable medium having instructions recorded thereon, the instructions when executed by a computer implementing the method described above.

### BRIEF DESCRIPTION OF THE DRAWINGS

The above aspects and other aspects and features will become apparent to those ordinarily skilled in the art upon review of the following description of specific embodiments in conjunction with the accompanying figures, wherein:

FIG. 1 schematically depicts a lithography apparatus, according to an embodiment.

FIG. 2 schematically depicts an embodiment of a lithographic cell or cluster, according to an embodiment.

FIG. 3 shows a flow chart for a method of determining existence of defects in a lithography process, according to an embodiment.

FIG. 4a illustrates how one isolated line of a pattern may have different optical proximity correction results, according to an embodiment.

FIG. 4b illustrates two patterns (for locations of interest) that include potential defects, according to an embodiment.

FIG. 5 illustrates a summary of operations that are part of the present methods and/or are performed by the present systems, according to an embodiment.

FIG. 6 illustrates converting one or more patterning process images comprising image patterns associated with a location of interest (e.g., a possible defect location) into feature vectors, according to an embodiment.

FIG. 7 illustrates grouping feature vectors with features indicative of image patterns that cause matching wafer or wafer defect behavior in the patterning process, according to an embodiment.

FIG. 8 depicts an example inspection apparatus, according to an embodiment.

FIG. 9 schematically depicts another example inspection apparatus, according to an embodiment.

FIG. 10 illustrates the relationship between an illumination spot of an inspection apparatus and a metrology target, according to an embodiment.

FIG. 11 schematically depicts a process of deriving a plurality of variables of interest based on measurement data, according to an embodiment.

FIG. 12 schematically depicts an embodiment of a scanning electron microscope (SEM), according to an embodiment.

FIG. 13 schematically depicts an embodiment of an electron beam inspection apparatus, according to an embodiment.

FIG. 14 illustrates example defects on a printed substrate, according to an embodiment.

FIG. 15 depicts an example flow chart for modeling and/or simulating at least part of a patterning process, according to an embodiment.

FIG. 16 is a block diagram of an example computer system, according to an embodiment.

FIG. 17 is a schematic diagram of a lithographic projection apparatus similar to FIG. 1, according to an embodiment.

FIG. 18 is a more detailed view of the apparatus in FIG. 17, according to an embodiment.

FIG. 19 is a more detailed view of the source collector module SO of the apparatus of FIG. 17 and FIG. 18, according to an embodiment.

### DETAILED DESCRIPTION

Optical proximity correction (OPC) enhances an integrated circuit patterning process by compensating for distortions that occur during processing. The distortions occur during processing because features printed on a wafer are smaller than the wavelengths of light used in the patterning and printing process. OPC verification identifies OPC errors or weak points in a post-OPC wafer design that could potentially lead to patterning defects on the wafer. ASML Tachyon Lithography Manufacturability Check (LMC) is an OPC verification product, for example.

To avoid missing potential defects, users often set tight inspection specifications and use various types of inspections during a lithography manufacturability check. This often results in many potential patterning defects being identified during the lithography manufacturability check for a full-chip (wafer) verification. It is difficult to manually review identified areas of a pattern and dispose of this large number of potential patterning defects. A widely accepted solution is to group similar potential patterning defects into groups and only manually review the worst several potential patterning defects inside each group. Potential patterning defects are assumed to be similar if the pattern designs in areas with potential patterning defects are similar. However, this is not always true. Often, defects behave differently even though they are associated with similar pattern designs. In addition, LMC process settings that define which pattern designs are considered similar or dissimilar may be overly narrow (making it more likely that potential patterning defects that behave similarly will be grouped in the same groups, but increasing the overall number of individual groups), or overly broad (making it more likely that potential patterning defects that behave differently will be grouped in the same group, but decreasing the overall number of individual groups).

New pattern grouping methods (and associated systems) that simultaneously reduce the overall group count and group potential patterning defects associated with matching defect behavior together in the same groups are described herein. Unlike prior grouping methods and systems, the present methods and systems utilize a trained machine learning model and/or other components to group patterns based on information from aerial, resist, and/or other images, instead of user design files (e.g., .gds files). Users need not specifically provide design information for the present methods and systems. The aerial, resist, and/or other images include image patterns associated with potential wafer defects in the patterning process. The present methods and systems group image (as compared to design) patterns to identify potential wafer defects in the patterning process that have (or will have) matching wafer (defect) behavior. As described herein, the present methods and systems make use of information in image buffers during image pattern grouping. These buffers store lithography manufacturability check model terms, imaging conditions, and/or other information that enhance grouping consistency (e.g., provide more vector features as described below) compared to traditional grouping processes based on only a gds layer (design file), for example.

The machine learning model is adaptively trained with labels (information) associated with actual wafer behavior (e.g., labeled wafer defects). The machine learning model uses the labels to learn to predict which image patterns are more or less likely to eventually turn into actual physical wafer defects and/or how those defects will behave. Among other advantages, this results in dramatically improved grouping efficiency (e.g., a balance between the number of groups and patterns in each group associated with matching behavior) compared to prior systems and methods. It also allows users to define and adjust what wafer (defect) behavior the users consider matching. Compared to prior methods and systems, the group count for the present methods and systems may be significantly decreased (when the same definition of matching behavior is used). Or, the wafer (defect) behavior is much more consistent within a group of the present methods and systems when the group count is the same as in prior methods and systems.

Even though the methods and systems are described throughout this disclosure as being associated with wafer defect behavior, it should be noted that these methods and systems may be used for grouping image patterns to determine any wafer behavior in a patterning process.

Before describing embodiments in detail, it is instructive to present an example environment in which embodiments may be implemented.

In one type of lithographic projection apparatuses, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information about lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”-generally the smallest feature size printed—and k₁ is an empirical resolution factor. In general, the smaller k₁ the more difficult it becomes to reproduce a pattern on the substrate that resembles the shape and dimensions planned by a designer to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

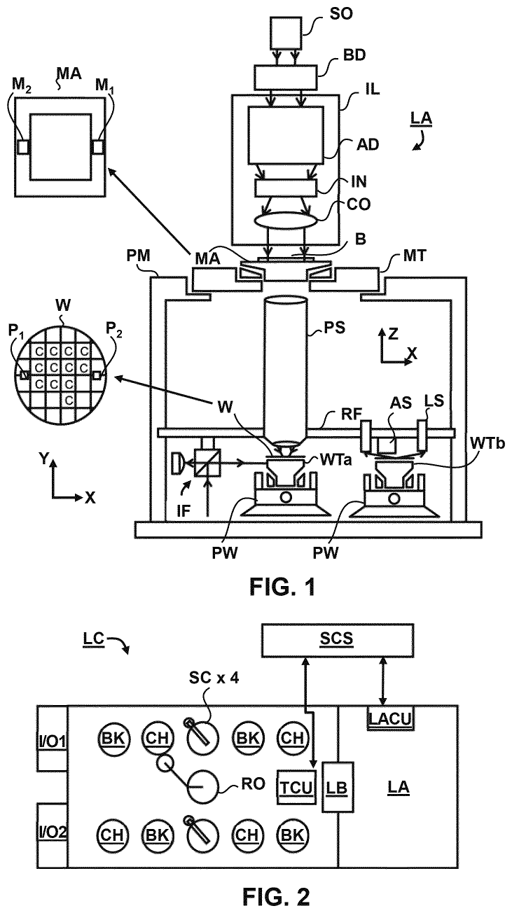

FIG. 1 schematically depicts an embodiment of a lithographic apparatus LA. The apparatus comprises:
an illumination system (illuminator) IL configured to condition a radiation beam B (e.g. UV radiation, DUV radiation, or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame (RF).

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AM configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AM. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation.

Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS has an optical transfer function which may be non-uniform, which can affect the pattern imaged on the substrate W. For unpolarized radiation such effects can be well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of basis functions. A particularly convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PS will have a different Zernike expansion for each field point (i.e. for each spatial location in its image plane). The relative phase of the projection system PS in its pupil plane may be determined by projecting radiation, for example from a point-like source in an object plane of the projection system PS (i.e. the plane of the patterning device MA), through the projection system PS and using a shearing interferometer to measure a wavefront (i.e. a locus of points with the same phase). A shearing interferometer is a common path interferometer and therefore, advantageously, no secondary reference beam is required to measure the wavefront. The shearing interferometer may comprise a diffraction grating, for example a two-dimensional grid, in an image plane of the projection system (i.e. the substrate table WT) and a detector arranged to detect an interference pattern in a plane that is conjugate to a pupil plane of the projection system PS. The interference pattern is related to the derivative of the phase of the radiation with respect to a coordinate in the pupil plane in the shearing direction. The detector may comprise an array of sensing elements such as, for example, charge coupled devices (CCDs).

The projection system PS of a lithography apparatus may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The diffraction grating may be sequentially scanned in two perpendicular directions, which may coincide with axes of a co-ordinate system of the projection system PS (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The transmission (apodization) of the projection system PS in its pupil plane may be determined by projecting radiation, for example from a point-like source in an object plane of the projection system PS (i.e. the plane of the patterning device MA), through the projection system PS and measuring the intensity of radiation in a plane that is conjugate to a pupil plane of the projection system PS, using a detector. The same detector as is used to measure the wavefront to determine aberrations may be used.

The projection system PS may comprise a plurality of optical (e.g., lens) elements and may further comprise an adjustment mechanism AM configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes:

1. In step mode, the support structure MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

Although specific reference may be made in this text to the use of lithography apparatus in the manufacture of ICs, it should be understood that the lithography apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example to create a multi-layer IC, so that the term substrate used herein may also refer to a substrate that already contains multiple processed layers.

The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that other patterns are not defective.

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers DE to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system MET that measures some or all of the substrates W that have been processed in the lithocell or other objects in the lithocell. The metrology system MET may be part of the lithocell LC, for example it may be part of the lithographic apparatus LA (such as alignment sensor AS).

The one or more measured parameters may include, for example, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, or may be performed after-etch.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). This can be done as described above and as described, for example, in U.S. patent application publication US 2006-066855, which is incorporated herein in its entirety by reference. Another application of diffraction-based metrology is in the measurement of feature width (CD) within a target. Such techniques can use the apparatus and methods described hereafter.

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

Within a metrology system MET, a metrology apparatus is used to determine one or more properties of the substrate, and in particular, how one or more properties of different substrates vary or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Examples of dark field metrology can be found in PCT patent application publication nos. WO 2009/078708 and WO 2009/106279, which are hereby incorporated in their entirety by reference. Further developments of the technique have been described in U.S. patent application publications US2011-0027704, US2011-0043791 and US2012-0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

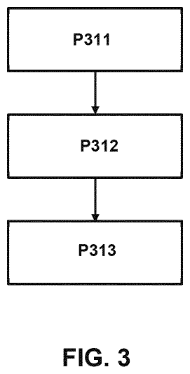

FIG. 3 shows a flow chart for a method of determining locations of potential defects (e.g., “hot spots”) in a lithography process, according to an embodiment. In process P311, the locations of interest are identified based on process design patterns. Specifics of the present method are described below, but generally, locations of interest may be identified by analyzing patterns on a patterning device using an empirical model or a computational model. In an empirical model, images (e.g., a resist image, an optical image, an etch image) of the patterns are not simulated. Instead, the empirical model predicts locations of interest based on correlations between processing parameters, parameters of the patterns, and the locations of interest. For example, an empirical model may be a classification model or a database of patterns prone to defects. In a computational model, a portion or a characteristic of the images is calculated or simulated, and locations of interest are identified based on the portion or the characteristic. For example, a location of interest corresponding to a potential line pull back defect may be identified by finding a line end too far away from its desired location. A location of interest corresponding to a potential bridging defect may be identified by finding a location where two lines undesirably join. A location of interest corresponding to a potential overlapping defect may be identified by finding two features on separate layers that undesirably overlap or undesirably not overlap. An empirical model is usually less computationally expensive than a computational model. It is possible to determine and/or compile process windows of the locations of interest into a map, based on the locations and process windows of individual locations—i.e., determine process windows as a function of location. This process window map may characterize the layout-specific sensitivities and processing margins of the patterns. In another example, the locations of interest and/or their process windows may be determined experimentally, such as by FEM wafer inspection or a suitable metrology tool. A set of locations of interest may include those locations that cannot be detected in an after-development-inspection (ADI) (usually optical inspection), such as resist top loss, resist undercut, etc. Conventional inspection may only reveal defects at the locations of interest after the substrate is irreversibly processed (e.g., etched), at which point the wafer cannot be reworked. However, simulation may be used to determine where defects may occur and what the severity may be. Based on this information, it may be either decided to inspect the specific hotspots/possible-defect using a more accurate inspection method (and typically more time consuming) to determine whether the defect/wafer needs rework, or it may be decided to rework the imaging of the specific resist layer (remove the resist layer having the resist top loss defect and recoat the wafer to redo the imaging of the specific layer) before the irreversible processing (e.g., etching) is performed.

In process P312, processing parameters under which the locations of interest are processed (e.g., imaged or etched onto a substrate) are determined. The processing parameters may be local—dependent on the locations, the dies, or both. The processing parameters may be global-independent of the locations and the dies. One exemplary way to determine the processing parameters is to determine the status of the lithographic apparatus. For example, laser bandwidth, focus, dose, source parameters, projection optics parameters, and the spatial or temporal variations of these parameters, may be measured from the lithographic apparatus. Another exemplary way is to infer the processing parameters from data obtained from metrology performed on the substrate, or from operator of the processing apparatus. For example, metrology may include inspecting a substrate using a diffractive tool (e.g., ASML YieldStar), an electron microscope, or other suitable inspection tools. It is possible to obtain processing parameters for any location on a processed substrate, including the identified locations of interest. The processing parameters may be compiled into a map-lithographic parameters, or process conditions, as a function of location. Of course, other processing parameters may be represented as functions of location, i.e., in a map. In an embodiment, the processing parameters may be determined before, and preferably immediately before processing each location of interest.

In process P313, existence, probability of existence, characteristics, or a combination thereof, of a potential defect at a location of interest is determined based on the processing parameters under which the location of interest is processed, and/or other information. This determination may comprise comparing the processing parameters and the process window of the location of interest-if the processing parameters fall within the process window, no defect exists; if the processing parameters fall outside the process window, at least one defect will be expected to exist. This determination may also be done using a suitable empirical model (including a statistical model). For example, a classification model may be used to provide a probability of existence of a defect. Another way to make this determination is to use a computational model to simulate an image or expected patterning contours of the location of interest under the processing parameters and measure the image or contour parameters. In an embodiment, the processing parameters may be determined immediately (i.e., before processing the pattern or the next substrate) after processing a pattern or a substrate. The determined existence and/or characteristics of a defect may serve as a basis for a decision of disposition: rework or acceptance. In an embodiment, the processing parameters may be used to calculate moving averages of the lithographic parameters. Moving averages are useful to capture long term drifts of the lithographic parameters, without distraction by short term fluctuations.

In an embodiment, locations of interest are identified based on the simulated image of a pattern on a substrate. Once the simulation of the patterning process (e.g., including process models such an OPC model and a manufacturability check model) is complete, potential weak points, i.e., locations of interest, in the design as a function of process conditions may be computed according to one or more definitions (e.g., certain rules, thresholds, or metrics). Locations of interest may be determined based on absolute CD values, on the rate of change of CD versus one or more of the parameters that were varied in the simulation (“CD sensitivity”), on the slope of the aerial image intensity, or on NILS (i.e., “edge slope,” or “normalized image log slope,” often abbreviated as “NILS.” (This indicates a lack of sharpness or image blur, where the edge of the resist feature is expected (computed from a simple threshold/bias model or a more complete resist model)). Alternatively, locations of interest may be determined based on a set of predetermined rules such as those used in a design rule checking system, including, but not limited to, line-end pullback, corner rounding, proximity to neighboring features, pattern necking or pinching, and other metrics of pattern deformation relative to the desired pattern. The CD sensitivity to small changes in mask CD is a lithographic parameter known as MEF (Mask Error Factor) or MEEF (Mask Error Enhancement Factor). Computation of MEF versus focus and exposure provides a metric for the probability that mask process variation convolved with wafer process variation will result in unacceptable pattern degradation of a particular pattern element. Locations of interest can also be identified based on variation in overlay errors relative to underlying or subsequent process layers and CD variation or by sensitivity to variations in overlay and/or CD between exposures in a multiple-exposure process.

In an embodiment, pattern fidelity metrology may be performed as guided defect inspection, where a simulation tool is used to identify patterns that are likely to fail, which guides the inspection system to locations in wafer where the identified patterns are located to improve efficiency of the inspection system. The inspection system acquires and analyzes pattern/hotspot/defect images on wafer. For example, wafer images may be acquired from a reflected image of an optical system (dark field or bright field inspection systems), or electron beam (e-beam) system.

The e-beam system has higher resolution than an optical system, but it is also comparatively slow and scanning the entire wafer image is not practical. To speed up the e-beam inspection (or even the optical system), simulations are configured to guide the inspection system to look at areas on the wafer where the likelihood of defects occurrence is relatively higher within the wafer. By doing so, the inspection process may be speed up by several order magnitudes without loss in defect capturing accuracy.

Each chip design contains a huge number of patterns, and only a small percent of patterns is likely to result in a defect. For example, these patterns may be the locations of interest or “hot spots.” Defects occur due to process variations (e.g., variations in process parameters such as focus and dose) and hot spots refer to those patterns that may fail first or have higher likelihood of failure due to such process variations. Process simulations may be performed to identify hot spots without requiring an actual wafer and an inspection tool.

Thus, guided inspection employs simulation to identify a very small number of locations of interest (“hot spots”) relative to a larger design layout of chip or a wafer, and then drives the inspection system to focus on inspecting areas on a wafer corresponding to patterns in the locations of interest, and not inspect the rest of a wafer, thereby increasing throughput by orders of magnitude.

Various aspects of pattern fidelity metrology and methods of hot spot determination or validation are discussed in detail in different patents/patent applications, which are incorporated herein in their entirety by reference. For example, U.S. patent application Ser. No. 15/546,592 describes a process variability aware adaptive inspection and metrology that discusses, for example, a defect prediction method based on variations in process parameters for finding defects. U.S. patent application Ser. No. 15/821,051 describes a hot spot identification based on process window or over lapping process window of an area of interest (e.g., a processing window limiting pattern or hot spot pattern) of a design layout. U.S. patent application Ser. No. 15/580,515 describes methods for defect validation that aligning the metrology image and the first image (e.g., a simulated image) of a wafer and employs verification flow and threshold feedback related to alignment/misalignment of the images. PCT patent application publication WO2017080729A1 describes methods for identifying a process window boundary that improves finding of hot spots.

Existing computational lithography related solutions (e.g., pattern fidelity metrology/monitoring for wafer defect inspection, as discussed earlier) employs modules (e.g., software) such as Computational Hotspot Detection (CHD) which uses computational lithography model to identify hot spots (locations of interest) in the full chip to guide an inspection apparatus (e.g., e-beam). CHD is configured to perform beyond OPC verification (e.g., defects related to OPC) and find process window defects, and may also generate hundreds of thousands of locations of interest (hot spots) for a full chip design. Due to a quick turn-around-time requirement and relatively low speed of making measurements using the inspection tool, inspection of only a small fraction (e.g., thousands out of a million) of the hot spots for full wafer may be performed. To address this problem, computational models employ a ranking indicator (also referred as a rank) to indicate a severity of individual hot spots. The severity of a hot spot is a measure of how likely the hot spot pattern is to transform into one or more physical wafer defects. For example, a high severity hot spot means that hot spot is likely to transform into a defect, and actual counts of such defects associated with the hot spot are likely it be relatively high compared to other patterns. Therefore, such a hot spot will also be ranked high. Whereas a low severity hot spot means a hot spot is less likely to transform into one or more defects, and actual defects counts on wafer are likely to be small or non-existent. Such a hot spot would be ranked low.

Based on the ranking, the inspection system may select a small fraction of the locations of interest (e.g., hot spots having relatively higher rank) for defect inspection. Therefore, accurate identification of the locations of interest (hot spots) and their severity/ranking is important to ensure a high capture rate (i.e., more true positives or more data that reveals defects related to patterns) and low nuisance rate (i.e., less false positive or less data related to non-defective patterns).

As mentioned earlier, measurements via a metrology tool are performed on a limited number of locations of interest (e.g., hot spot locations) on a printed wafer due to an amount of time and resources required to make measurements. An incorrect hot spot ranking may guide an inspection apparatus to less critical (e.g., non-hot spot locations) locations on a printed substrate, thereby spending (or wasting) tool time for inspecting patterns that are unlikely to result in real defects.

After mask design including OPC for assist features (e.g., SRAF and SERIF), a next step is mask verification, such as OPC verification. The mask verification is a standard step in mask data preparation (MDP) flow for reticle tape-out before sending the mask design for manufacturing or fabrication facility. The purpose of such mask verification is to identify errors or weak points in the post-OPC design that would potentially lead to patterning defects on a printed substrate. In an embodiment, such mask verification can be performed using software employing lithographic manufacturability checks (LMC or LMC+) such as Tachyon software employing LMC rules. LMC+ may refer to a lithography verification platform configured to address verification challenges at advanced nodes (1× and sub-10 nm tech nodes). The re-architecture focuses on three major objectives: accuracy, performance, and ease-of-use. LMC+ may include elements such as core engines for image/contour simulation and defect measurement, flexible inspection flow, and user configurable detectors. The accuracy of the mask verification depends on an accuracy of a patterning process model including an OPC model. Inaccuracy in the process model results in missing real defects on then substrate or nuisance defects that are not real. In an embodiment, a defect refers to a feature or a portion of the feature that is out of specification when imaged on the substrate. For example, a defect can be necking, hole closure, merging holes, etc.

Some of the defects identified via the LMC are also sent for a substrate inspection or monitoring. In an embodiment, a location on the mask corresponding to the defect identified by LMC is referred as a location of interest or hot spot. In an embodiment, a location of interest (hot spot) can be defined as a location on the mask having a high likelihood of becoming a real defect when a pattern associated with the location of interest (hot spot) is imaged on the substrate.

For example, ASML's pattern fidelity metrology (PFM) product relies on certain patterns or locations thereof (e.g., hot spots) identified by LMC to guide an e-beam inspection to only particular locations on a printed substrate to improve efficiency. Due to the turn-around-time requirement for PFM and the speed of the inspection tool, PFM is only able to inspect a small fraction, usually in thousands, of these locations (e.g., hot spots) of a full printed substrate. To address this inspection problem, desired patterns (e.g., related to the hot spots) identified by LMC need to be ranked based on their likelihood of becoming real defects when imaged on the substrate, and PFM relies on such hot spot ranking to select a small fraction of the hot spots for inspection. Therefore, accurate identification of the locations of interest (hot spots) and their severity is one step that may be performed to ensure the high capture rate and low nuisance rate of PFM.

The process model including the OPC model may be inaccurate due to several approximations used to improve the speed of a simulation process. Thus, a more conservative approach is used where a tight specification is applied to a pattern or a feature therein so that no potential defects are missed. The consequence however is that a large number of locations of interest that correspond to nuisance defects, i.e., defects that may not appear on a real printed substrate, are inspected.

An error in defect identification via LMC may also affect a ranking of the locations of interest (hot spots). When the ranking is not accurate, a wrong hot spot list is used for guided inspection, which may result in missing real defects on the printed substrate since they may not be in the sampled hot spot lists, or a large number of nuisance defects may be used that waste inspection time.

As described above, the methods and systems described herein facilitate grouping of image pattern locations of interest (associated with potential defects) with a reduced overall group count, while still grouping potential patterning defects associated with matching defect behavior together in the same groups. More generally, the present methods and systems may be used for grouping any image patterns to determine wafer behavior in a patterning process. The present methods and systems utilize a trained machine learning model, as described below. This improves the LMC (and/or LMC+) process for a user and/or has other advantages.

Current LMC and/or LMC+ grouping methods are based on a user-defined gds (e.g., an electronic file type that defines the design) layer. The gds layer is usually a pre-resolution enhancement techniques (RET) design. Defects with the same pattern matching (PM) layer in a certain matching range are grouped into the same group. The PM range is a key factor in the current grouping process. Too large a PM range leads to a large group count, while too small a PM range causes grouping of designs associated with potential defects having different behaviors into the same group. As the technode keeps shrinking, the potential defect count and potential defect shape diversity both increase. Thus, it has become more challenging to achieve a balance between accurate behavior-based grouping and the overall number of groups. Moreover, the PM range is usually a global value which applies to all patterns equally, while a more suitable PM range may be determined based on a combination of imaging conditions and pattern geometry that varies from pattern to pattern.

In a typical system, a pre-RET design is often used for the PM layer, which means individual patterns (with potential defect locations of interest) with the same pre-RET design in the defined PM range would be considered to have the same wafer behavior (e.g., for grouping or some other future disposition). However, individual patterns often have very different post-RET configurations and sbar (for example) placements (and thus very different behavior), even though their pre-RET designs were the same. Although the contour CD for individual patterns around different potential defect locations may be similar due to constraints in the OPC correction process, the aerial images (AI) and resist images (RI) for the individual patterns around potential defect locations may have significant differences, which may lead to large differences in eventual on-wafer pattern (e.g., defect) behavior.

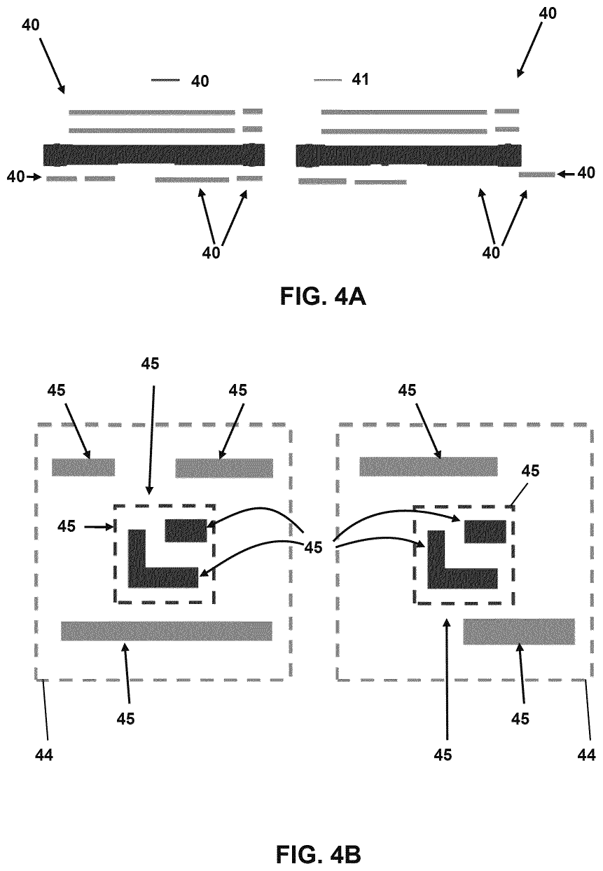

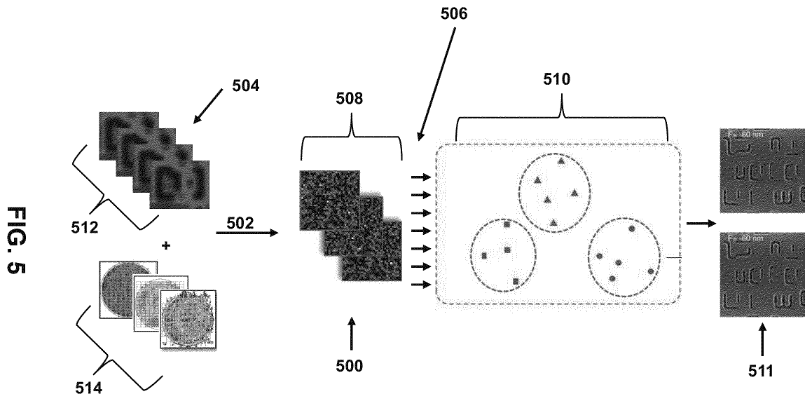

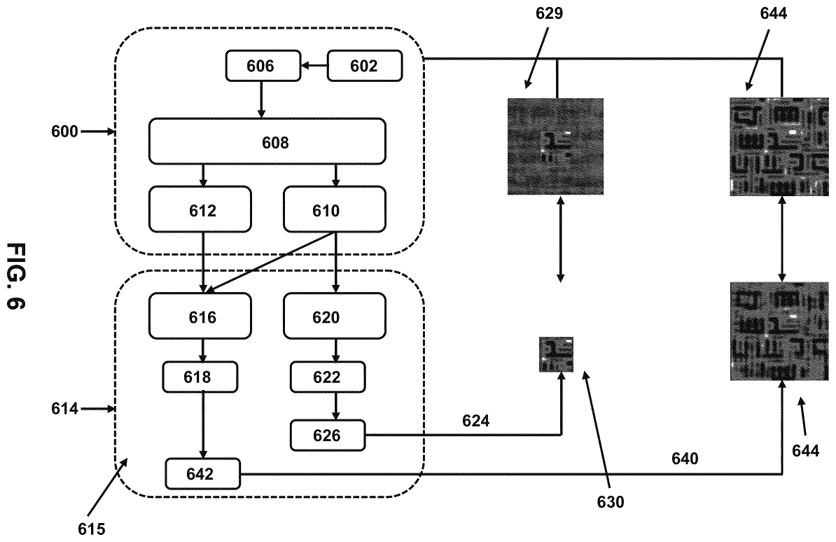

By way of a non-limiting example, FIG. 4a illustrates how one isolated line 400 of a pattern 402 may have different OPC correction results 404 and 406. FIG. 4a illustrates a main OPC structure 408 and sub resolution assist feature(s) (SRAF) 410. As shown in FIG. 4a, the same pre-RET design (pattern 402) may have different scatter bar (SBAR) and/or other post-RET configurations 404 and 406. A pre-RET design was used for the PM layer (not shown in FIG. 4a). As described above, individual patterns (with potential defect locations of interest) with the same pre-RET design in the defined PM range would be considered to have the same wafer behavior (e.g., for grouping or some other future disposition). However, as shown in FIG. 4a, individual patterns often have different post-RET configurations and sbar (for example) placements (and thus very different behavior), even though their pre-RET designs were the same.

Various factors may affect a defect's eventual on-wafer behavior. These factors are sensitive to long range pattern features (e.g., surrounding features outside of the immediate area of image pattern locations of interest associated with potential defects). Unfortunately, in typical systems, most long-range features that would affect after-resist (eventual) wafer (e.g., defect) behaviors are not considered for LMC and/or LMC+. By way of a non-limiting example, FIG. 4b illustrates two patterns (for the locations of interest) 446 and 448 that include potential defects 450 and 452. Areas 451 and 453 (e.g., pattern matching (PM) ranges in a typical system) of patterns 446 and 448 appear to have the same design 454, and thus would be grouped in the same group by a typical system. However, if different long-range features 456 and 458 of patterns 446 and 448 are considered, potential defects 450 and 452 may eventually behave differently on wafer because of different long-range features 456 and 458 surrounding defects 450 and 452.

In contrast to typical systems, instead of using a pre-RET design (e.g., a .gds file) and ignoring long range features, the present methods and systems utilize patterning process images (e.g., aerial images, resist images, etc.) and consider long range features, among other information, when grouping image patterns that cause matching (e.g., defect or other) wafer behavior in the patterning process. These new pattern grouping methods and systems eliminate disadvantages of grouping based on a pre-RET design. The present methods and systems are configured to consider aerial images, resist images, etc., short and long range pattern features, and/or other information, such that patterns indicative of defects having the same design within a limited range are separated into different groups if their eventual on-wafer behavior is predicted to differ. At the same time, the present methods and systems are configured such that patterns indicative of defects with different designs but matching on-wafer behavior are grouped together.

Since eventual on-wafer behavior is difficult to detect (e.g., mean CD/EP error in comparison with a simulated result or other index extracted from a wafer SEM image), the present methods and systems utilize machine learning based pattern grouping, where a machine learning model is trained to predict eventual wafer (and/or wafer defect) behavior based on (aerial, resist, etc.) images of patterns.

As an example, the machine learning model may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

The one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be more free flowing, with connections interacting in a more chaotic and complex fashion. In some embodiments, the intermediate layers of the one or more neural networks include one or more convolutional layers, one or more recurrent layers, and/or other layers.

The one or more neural networks may be trained using training data. The training data may include a set of training samples. Each sample may be a pair comprising an input object (patterning process images comprising image patterns for the locations of interest (e.g., locations that include potential defects) and/or vectors associated with specific images, which may be called feature vectors) and a desired output value (also called the supervisory signal), such as an indication of eventual wafer and/or defect behavior. A training algorithm analyzes the training data and adjusts the behavior of the neural network by adjusting the parameters (e.g., weights of one or more layers) of the neural network based on the training data. For example, given a set of N (the count of the input data set) training samples of the form {(x₁,y₁), (x₂,y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is a vector that represents some object (e.g., a pattern image as in the example above). The dimension of the feature vector depends on the neural network structure. In some embodiments, input samples may be a single object or an object/feature vector pair, also depending on the neural network structure. The vector space associated with these vectors is often called the feature space. After training, the neural network may be used for making predictions using new samples.

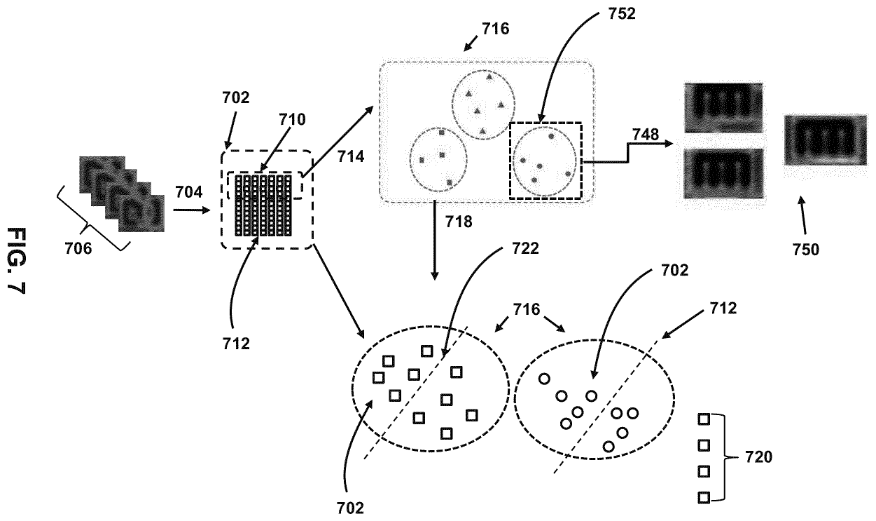

FIG. 5 illustrates a summary of operations 500 that are part of the present methods and/or are performed by the present systems. For example, the present method comprises converting 502, based on the trained machine learning model, one or more patterning process images 504 comprising image patterns for the locations of interest (e.g., possible defect locations) into feature vectors 506. Feature vectors 506 correspond to features 508 of the image patterns. The present method comprises grouping 510, based on the trained machine learning model, feature vectors with features indicative of image patterns that cause matching (e.g., defect or other) wafer behavior in the patterning process. In some embodiments, the present methods for grouping image patterns to determine wafer behavior are methods for grouping image patterns to identify potential wafer defects in the patterning process, and the methods comprise grouping 510, based on the trained machine learning model, feature vectors with features indicative of image patterns that cause matching wafer defect behavior in the patterning process. In some embodiments, as shown in FIG. 5, the present methods include one or more verification operations 511 (e.g., SEM inspection of physical wafers with defects predicted by the machine learning model to have the same defect behavior, etc.) configured to verify that the groupings predicted by the machine learning model included defects that produced matching defect behavior (which may be used to train the machine learning model, for example).

In some embodiments, the one or more patterning process images comprise aerial images, resist images, and/or other images 512. In some embodiments, the present methods are used during an OPC portion of the patterning process. In some embodiments, the grouped feature vectors are used to detect potential patterning defects on a wafer during a lithography manufacturability check. For example, during an LMC operation, aerial images, resist images, mask images, and/or other images may be generated and stored as temporary files. In some embodiments, the feature vectors describe the image patterns and include features related to LMC and/or LMC+ model terms and/or imaging conditions 514 (e.g., a scanner fingerprint) for the one or more patterning process images. However, other uses of the present method are contemplated.

In some embodiments, the trained machine learning model comprises a first trained machine learning model and a second trained machine learning model, and/or other trained machine learning models. In some embodiments, converting the one or more patterning process images comprising the image patterns into feature vectors is based on the first trained machine learning model. In some embodiments, the first machine learning model is an image encoder (e.g., a convolutional neural network) trained to extract features from aerial images and/or resist images indicative of short-range aerial and/or resist image pattern configurations and long-range pattern structures that influence the wafer or wafer defect behavior. In some embodiments, feature extraction separates local features from global features of the images. The first machine learning model is configured to encode the extracted features into the feature vectors. In other words, individual aerial and/or resist images comprising image patterns for the locations of interest (e.g., possible defect locations) are encoded and compressed into low dimension feature vectors (which can also be decoded back into aerial and/or resist images with limited distortion compared to the original images).

FIG. 6 illustrates converting 600 one or more patterning process images 602 comprising the image patterns associated with a location of interest (e.g., a possible defect location) into feature vectors. Converting the one or more patterning process images comprising the image patterns associated with a location of interest (e.g., a possible defect location) into feature vectors may be and/or include encoding the one or more patterning process images into feature vectors with an encoder 604 (e.g., encoder architecture) of the first machine learning model and/or other machine learning models. In the example shown in FIG. 6, patterning process images 602 may be 128×128×3 (this resolution is not intended to be limiting) mask images, aerial images, resist images, and/or other images. In the example shown in FIG. 6, converting and/or encoding 600 includes inputting images 602 into a (e.g., convolutional encoder portion of a) neural network 606, performing a flatting operation 608, and extracting and encoding short range 610 and long range 612 features into feature vectors. The specific example shown in FIG. 6 should not be considered limiting. The present methods and systems may use one or more other techniques for image compression.

FIG. 6 also illustrates decoding 614 the feature vectors back into images 616. Images 616 may be similar to and/or the same as images 602 in this example. Decoding 614 may be performed with a decoder 615 (decoder architecture) of the first machine learning model and/or other machine learning models. As shown in FIG. 6, decoding 614 may include decoding and/or deconvolution operations 616, 618, 620, and 622 performed based on short range features 610 and/or long-range features 612 of the feature vectors. In some embodiments, decoding and/or deconvolution operations 616, 618, 620, and 622 include operations 616 and 620, and convolutional decoding operations 618 and 622. (For example, the neural network may be fully connected such that all neurons in a previous layer are connected to each neuron in a current layer to enable every neuron in the current layer to process all information from the previous layer.) Decoding and/or deconvolution operations 620 and 622 form a portion of pathway 624 and output 626 images 628 or portions of an image 630 associated with a center region (e.g., at or near a possible defect location) of an image based on short range features 610. These images 628 or portions of an image 630 may have a resolution, for example, of 32×32×3 (this is not intended to be limiting). This may comprise high recovery with low-dimension short range features, for example. Decoding and/or deconvolution operations 616 and 618 form a portion of pathway 640 and output 642 full images 644 based on short range features 610 and/or long-range features 612. These images 642 may have a resolution, for example, of 128×128×3 (this is not intended to be limiting). This may comprise medium recovery with high-dimension (e.g., all) features, for example.

In some embodiments, the first machine learning model comprises a loss function. As such, the first machine learning model is configured such that some image information is dropped after the (encoding) compression step. However, the first machine learning model is trained such that relevant image information related to wafer (defect) behavior is not dropped. For example, features in a center region of image (e.g., 630 shown in FIG. 6) may be weighted (as part of loss function for example) higher than features from other regions of the image. In some embodiments, the first machine learning model is trained with simulated aerial images and/or resist images. In some embodiments, the first machine learning model is iteratively re-trained based on output from the first machine learning model and additional simulated aerial and/or resist images. In some embodiments, the first machine learning model comprises the loss function, and iteratively re-training the first machine learning model based on the output from the first machine learning model and the additional simulated aerial and/or resist images comprises adjusting the loss function.

In some embodiments, grouping feature vectors with features indicative of image patterns that cause matching wafer or wafer defect behavior is based on the second trained machine learning model. In some embodiments, this grouping may be and/or include clustering and/or other forms of grouping. In some embodiments, grouping the feature vectors with features indicative of image patterns that cause matching wafer or wafer defect behavior based on the second machine learning model comprises grouping the feature vectors into first groups based on the features indicative of the short range aerial and/or resist image pattern configurations, and grouping the feature vectors into second groups based on the first groups and the long range pattern structures that influence the wafer or wafer defect behavior.

The features indicative of the short-range aerial and/or resist image pattern configurations include the features related to LMC and/or LMC+ model terms and/or imaging conditions for the one or more patterning process images, and/or other information. This information does not include for example, information about wafer defect behavior. Grouping the feature vectors into first groups may be a rough clustering, for example, where images that correspond to the vectors in a given first group share similar aerial and/or resist image patterns in the locations of interest (e.g., at or near portions of the patterns that correspond to potential wafer defects).

The second groups comprise the groups of feature vectors with the features indicative of image patterns that cause the matching wafer or wafer defect behavior in the patterning process. The second groups are grouped (or clustered) based on the full feature vectors (short and long range image pattern configuration features, features related to LMC and/or LMC+ model terms and/or imaging conditions, etc.). The second machine learning model is trained with labeled wafer defects from a wafer verification process (e.g., operation 511 shown in FIG. 5). For example, as part of an LMC and/or LMC+ operation, large scale aerial, resist, and/or other images of patterns at or near potential defect locations are paired with actual defect coordinate information. In some embodiments, a given labeled wafer defect includes information related to short range aerial and/or resist image pattern configurations associated with the given labeled wafer defect, long range pattern structures associated with the given labeled wafer defect, behavior of the given labeled wafer defect in the patterning process, coordinates of a location of the given labeled wafer defect and a critical dimension at that location, an indication of whether the given labeled wafer defect is a real defect or not, information related to an exposure of an image of the given labeled wafer defect at the location (e.g., delta_focus, delta dos, overlay error, and/or other process error), and/or other information. In some embodiments, the information related to the short-range aerial and/or resist image pattern configurations associated with the given labeled wafer defect, and the long-range pattern structures associated with the given labeled wafer defect, are related to a probability of whether the given labeled wafer defect is real or not.

With this training, and the full feature vectors as input, the second machine learning model outputs the second groups of feature vectors (where the second groups comprise the groups of feature vectors with the features indicative of image patterns that cause the matching wafer or wafer defect behavior in the patterning process). In some embodiments, the second machine learning model is iteratively re-trained based on output from the second machine learning model, the given labeled wafer defect, additional labeled wafer defects from the wafer verification process, and/or other information.

FIG. 7 illustrates grouping 700 feature vectors 702 with features indicative of image patterns that cause the matching wafer or wafer defect behavior in the patterning process. FIG. 7 illustrates converting (encoding) 704 one or more patterning process images 706 comprising the image patterns associated with a location of interest (e.g., a possible defect location) into feature vectors 702 (also shown in FIG. 6). Feature vectors 702 have short range 710 and long range 712 features. FIG. 7 illustrates grouping 714 feature vectors 702 into (“rough”) first groups 716 based on the features 710 indicative of the short-range aerial and/or resist image pattern configurations (e.g., grouping geometrically similar images), and grouping 718 the feature vectors into second groups 720, 722 based on first groups 716, short range features 710, and the long-range pattern structures 712 (e.g., all features) that influence the wafer or wafer defect behavior (e.g., both short range 710 and long range 712 features influence wafer defect behavior). FIG. 7 also illustrates 748 how feature vectors 702 grouped into first groups 716 share similar corresponding aerial and/or resist images 750 within a group 752.

In some embodiments, the method comprises identifying groups of potential wafer defects that have matching wafer defect behavior in the patterning process based on the grouping of the feature vectors with the features indicative of image patterns that cause the matching wafer defect behavior in the patterning process. This may include, for example, human inspection of potential defects in each group that have been ranked, etc., as described above. In the example shown in FIG. 7, defect candidates eventually examined by SEM may be labeled as risky or safe. These risky and safe defects should have been grouped in different groups by the machine learning models. If not, this information may be fed back into the model(s) to further train the model(s). New SEM verification labels may be continuously fed into second machine learning model to improve the final (second) grouping (clustering) result. This example is not intended to be limiting. It should be noted that the user may also use other criteria to separate different wafer behaviors and re-train the second machine learning model (and/or any other machine learning models of the present methods and systems) to output enhanced grouping results.

In some embodiments, the method comprises adjusting a mask layout design of a mask of the patterning process based on the groups of potential wafer defects that have the matching wafer defect behavior in the patterning process. In some embodiments, the method is used to generate a gauge line/defect candidate list to enhance accuracy and efficiency of wafer verification. For example, when a user identifies a few confirmed wafer defects locations, the system may be configured to trace the defects back to the groups they belong to. Other defect candidates inside same group may have a higher risk that they are also wafer defects. The present system maybe configured to provide the locations of other high-risk candidates in the form of a gauge line file and/or in other forms. In some embodiments, the method further comprises predicting, based on the trained machine learning model, a ranking indicator to indicate a relative severity of individual potential wafer defects. The ranking indicator may be a measure of how likely a potential wafer defect is to transform into one or more physical wafer defects. This way, higher risk potential defects may be prioritized for inspection and/or other purposes, for example. As another example, when user finishes grouping with a ML method, there may exist some groups without any images inside them that have been inspected by SEM for verification. As the wafer behavior inside each group determined by the present system would be much more consistent than traditional grouping methods, the user may randomly pick one or several locations from each group for further SEM verification. Other applications are contemplated.

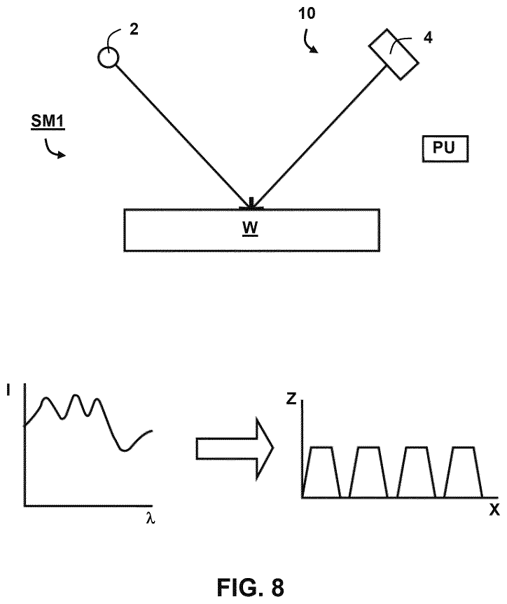

FIG. 8 depicts an example inspection apparatus (e.g., a scatterometer). It comprises a broadband (white light) radiation projector 2 which projects radiation onto a substrate W. The redirected radiation is passed to a spectrometer detector 4, which measures a spectrum 10 (intensity as a function of wavelength) of the specular reflected radiation, as shown, e.g., in the graph in the lower left of FIG. 8. From this data, the structure or profile giving rise to the detected spectrum may be reconstructed by processor PU, e.g. by Rigorous Coupled Wave Analysis and non-linear regression or by comparison with a library of simulated spectra as shown at the bottom right of FIG. 8. In general, for the reconstruction the general form of the structure is known and some variables are assumed from knowledge of the process by which the structure was made, leaving only a few variables of the structure to be determined from the measured data. Such an inspection apparatus may be configured as a normal-incidence inspection apparatus or an oblique-incidence inspection apparatus.

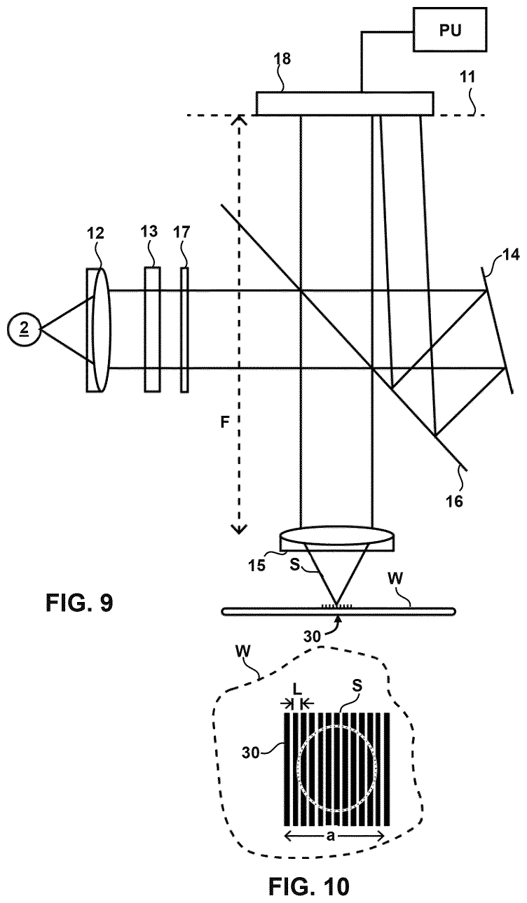

Another inspection apparatus that may be used is shown in FIG. 9. In this device, the radiation emitted by radiation source 2 is collimated using lens system 12 and transmitted through interference filter 13 and polarizer 17, reflected by partially reflecting surface 16 and is focused into a spot S on substrate W via an objective lens 15, which has a high numerical aperture (NA), desirably at least 0.9 or at least 0.95. An immersion inspection apparatus (using a relatively high refractive index fluid such as water) may even have a numerical aperture over 1.

As in the lithographic apparatus LA (FIG. 1), one or more substrate tables may be provided to hold the substrate W during measurement operations. The substrate tables may be similar or identical in form to the substrate table WT of FIG. 1. In an example where the inspection apparatus is integrated with the lithographic apparatus, they may even be the same substrate table. Coarse and fine positioners may be provided to a second positioner PW configured to accurately position the substrate in relation to a measurement optical system. Various sensors and actuators are provided for example to acquire the position of a target of interest, and to bring it into position under the objective lens 15. Typically, many measurements will be made on targets at different locations across the substrate W. The substrate support can be moved in X and Y directions to acquire different targets, and in the Z direction to obtain a desired location of the target relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and only the substrate moves. Provided the relative position of the substrate and the optical system is correct, it does not matter in principle which one of those is moving in the real world, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

The radiation redirected by the substrate W then passes through partially reflecting surface 16 into a detector 18 in order to have the spectrum detected. The detector 18 may be located at a back-projected focal plane 11 (i.e., at the focal length of the lens system 15) or the plane 11 may be re-imaged with auxiliary optics (not shown) onto the detector 18. The detector may be a two-dimensional detector so that a two-dimensional angular scatter spectrum of a substrate target 30 can be measured. The detector 18 may be, for example, an array of CCD or CMOS sensors, and may use an integration time of, for example, 40 milliseconds per frame.

A reference beam may be used, for example, to measure the intensity of the incident radiation. To do this, when the radiation beam is incident on the partially reflecting surface 16 part of it is transmitted through the partially reflecting surface 16 as a reference beam towards a reference mirror 14. The reference beam is then projected onto a different part of the same detector 18 or alternatively on to a different detector (not shown).

One or more interference filters 13 are available to select a wavelength of interest in the range of, say, 405-790 nm or even lower, such as 200-300 nm. The interference filter may be tunable rather than comprising a set of different filters. A grating could be used instead of an interference filter. An aperture stop or spatial light modulator (not shown) may be provided in the illumination path to control the range of angle of incidence of radiation on the target.

The detector 18 may measure the intensity of redirected radiation at a single wavelength (or narrow wavelength range), the intensity separately at multiple wavelengths or integrated over a wavelength range. Furthermore, the detector may separately measure the intensity of transverse magnetic- and transverse electric-polarized radiation and/or the phase difference between the transverse magnetic- and transverse electric-polarized radiation.

The target 30 on substrate W may be a 1-D grating, which is printed such that after development, the bars are formed of solid resist lines. The target 30 may be a 2-D grating, which is printed such that after development, the grating is formed of solid resist pillars or vias in the resist. The bars, pillars or vias may be etched into or on the substrate (e.g., into one or more layers on the substrate). The pattern (e.g., of bars, pillars or vias) is sensitive to change in processing in the patterning process (e.g., optical aberration in the lithographic projection apparatus (particularly the projection system PS), focus change, dose change, etc.) and will manifest in a variation in the printed grating. Accordingly, the measured data of the printed grating is used to reconstruct the grating. One or more parameters of the 1-D grating, such as line width and/or shape, or one or more parameters of the 2-D grating, such as pillar or via width or length or shape, may be input to the reconstruction process, performed by processor PU, from knowledge of the printing step and/or other inspection processes.

In addition to measurement of a parameter by reconstruction, angle resolved scatterometry is useful in the measurement of asymmetry of features in product and/or resist patterns. A particular application of asymmetry measurement is for the measurement of overlay, where the target 30 comprises one set of periodic features superimposed on another. The concepts of asymmetry measurement using the instrument of FIG. 8 or FIG. 9 are described, for example, in U.S. patent application publication US2006-066855, which is incorporated herein in its entirety. Simply stated, while the positions of the diffraction orders in the diffraction spectrum of the target are determined only by the periodicity of the target, asymmetry in the diffraction spectrum is indicative of asymmetry in the individual features which make up the target. In the instrument of FIG. 9, where detector 18 may be an image sensor, such asymmetry in the diffraction orders appears directly as asymmetry in the pupil image recorded by detector 18. This asymmetry can be measured by digital image processing in unit PU, and calibrated against known values of overlay.

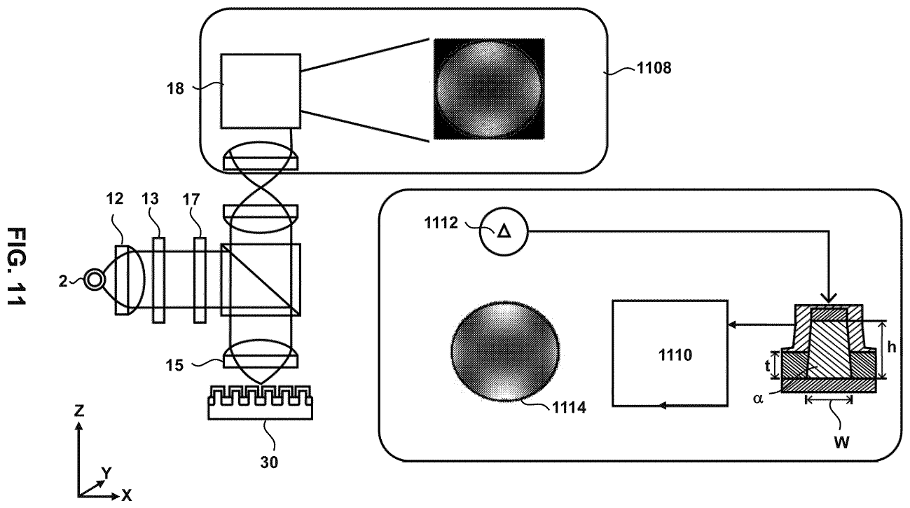

FIG. 10 illustrates a plan view of a typical target 30, and the extent of illumination spot S in the apparatus of FIG. 9. To obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target in other words is ‘underfilled’ by the illumination, and the diffraction signal is essentially free from any signals from product features and the like outside the target itself. The illumination arrangement 2, 12, 13, 17 (FIG. 9) may be configured to provide illumination of a uniform intensity across a back focal plane of objective 15. Alternatively, by, e.g., including an aperture in the illumination path, illumination may be restricted to on axis or off axis directions.

FIG. 11 schematically depicts an example process of the determination of the value of one or more variables of interest of a target pattern 30 based on measurement data obtained using metrology. Radiation detected by the detector 18 provides a measured radiation distribution 1108 for target 30. For a given target 30, a radiation distribution 1112 can be computed/simulated from a parameterized model 1106 using, for example, a numerical Maxwell solver 1110. The parameterized model 1106 shows example layers of various materials making up, and associated with, the target. The parameterized model 1106 may include one or more of variables for the features and layers of the portion of the target under consideration, which may be varied and derived. As shown in FIG. 11, the one or more of the variables may include the thickness t of one or more layers, a width w (e.g., CD) of one or more features, a height h of one or more features, and/or a sidewall angle α of one or more features. Although not shown, the one or more of the variables may further include, but is not limited to, the refractive index (e.g., a real or complex refractive index, refractive index tensor, etc.) of one or more of the layers, the extinction coefficient of one or more layers, the absorption of one or more layers, resist loss during development, a footing of one or more features, and/or line edge roughness of one or more features. The initial values of the variables may be those expected for the target being measured. The measured radiation distribution 1108 is then compared at 1112 to the computed radiation distribution 1112 to determine the difference between the two. If there is a difference, the values of one or more of the variables of the parameterized model 1106 may be varied, a new computed radiation distribution 1112 calculated and compared against the measured radiation distribution 1108 until there is sufficient match between the measured radiation distribution 1108 and the computed radiation distribution 1112. At that point, the values of the variables of the parameterized model 1106 provide a good or best match of the geometry of the actual target 30. In an embodiment, there is sufficient match when a difference between the measured radiation distribution 1108 and the computed radiation distribution 1112 is within a tolerance threshold.

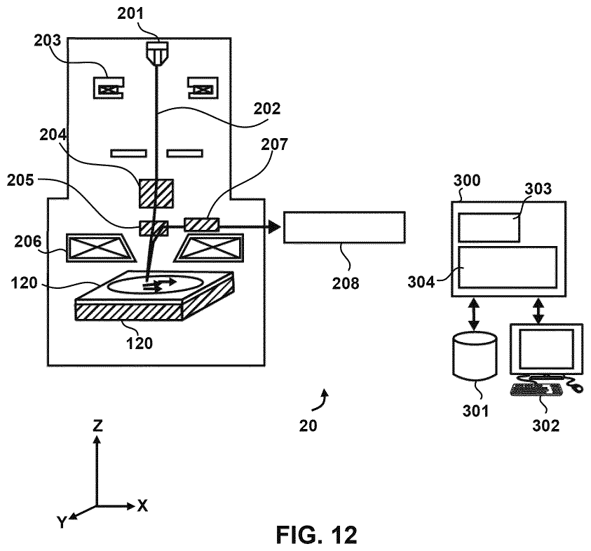

FIG. 12 schematically depicts an embodiment of an electron beam inspection apparatus 200. A primary electron beam 202 emitted from an electron source 201 is converged by condenser lens 203 and then passes through a beam deflector 204, an E×B deflector 205, and an objective lens 206 to irradiate a substrate 1200 on a substrate table 1201 at a focus.

When the substrate 1200 is irradiated with electron beam 202, secondary electrons are generated from the substrate 1200. The secondary electrons are deflected by the E×B deflector 205 and detected by a secondary electron detector 207. A two-dimensional electron beam image can be obtained by detecting the electrons generated from the sample in synchronization with, e.g., two-dimensional scanning of the electron beam by beam deflector 204 or with repetitive scanning of electron beam 202 by beam deflector 204 in an X or Y direction, together with continuous movement of the substrate 1200 by the substrate table 1201 in the other of the X or Y direction. Thus, in an embodiment, the electron beam inspection apparatus has a field of view for the electron beam defined by the angular range into which the electron beam can be provided by the electron beam inspection apparatus (e.g., the angular range through which the deflector 204 can provide the electron beam 202). Thus, the spatial extent of the field of the view is the spatial extent to which the angular range of the electron beam can impinge on a surface (wherein the surface can be stationary or can move with respect to the field).

A signal detected by secondary electron detector 207 is converted to a digital signal by an analog/digital (A/D) converter 208, and the digital signal is sent to an image processing system 300. In an embodiment, the image processing system 300 may have memory 303 to store all or part of digital images for processing by a processing unit 304. The processing unit 304 (e.g., specially designed hardware or a combination of hardware and software or a computer readable medium comprising software) is configured to convert or process the digital images into datasets representative of the digital images. In an embodiment, the processing unit 304 is configured or programmed to cause execution of a method described herein. Further, image processing system 300 may have a storage medium 301 configured to store the digital images and corresponding datasets in a reference database. A display device 302 may be connected with the image processing system 300, so that an operator can conduct necessary operation of the equipment with the help of a graphical user interface.

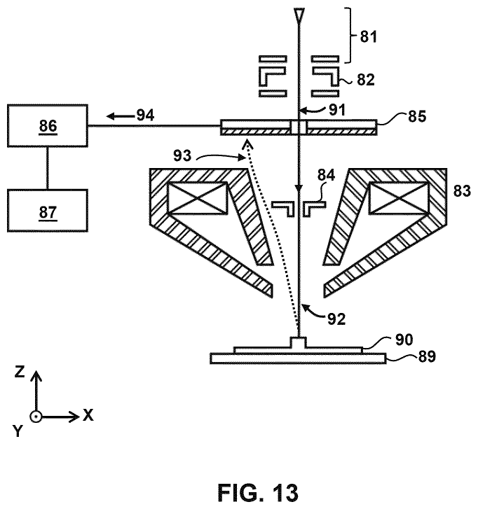

FIG. 13 schematically illustrates a further embodiment of an inspection apparatus. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 12 that uses a probe to inspect a substrate, the electron current in the system of FIG. 13 is significantly larger compared to, e.g., a CD SEM such as depicted in FIG. 12, such that the probe spot is large enough so that the inspection speed can be fast. However, the resolution may not be as high as compared to a CD SEM because of the large probe spot. In an embodiment, the above discussed inspection apparatuses may be single beam or a multi-beam apparatus without limiting the scope of the present disclosure.

The SEM images, from, e.g., the system of FIG. 12 and/or FIG. 13, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images.

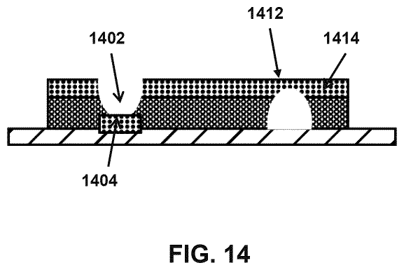

FIG. 14 illustrates example defects such as a footing 1402 and necking 1412 defect types. These may be observed for certain setting of the process variables such as dose/focus. For footing defects, de-scumming may be performed to remove a foot 1404 at the substrate. For necking 2412 defects, a resist thickness may be reduced by removing a top layer 1414. In an embodiment, another defect behavior may be whether the defects resulting from some locations of interest are fixable or not via a post-patterning process. For example, locations of interest that lead to defects that may be fixed post-patterning process and occur less frequently than other defects may be grouped together.

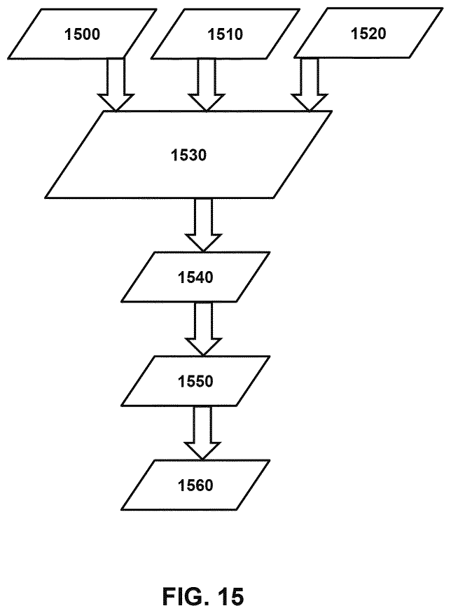

An exemplary flow chart for modelling and/or simulating parts of a patterning process is illustrated in FIG. 15. As will be appreciated, the models may represent a different patterning process and need not comprise all the models described below. A source model 1500 represents optical characteristics (including radiation intensity distribution, bandwidth and/or phase distribution) of the illumination of a patterning device. The source model 1500 can represent the optical characteristics of the illumination that include, but not limited to, numerical aperture settings, illumination sigma (c) settings as well as any particular illumination shape (e.g. off-axis radiation shape such as annular, quadrupole, dipole, etc.), where sigma is outer radial extent of the illuminator.

A projection optics model 1510 represents optical characteristics (including changes to the radiation intensity distribution and/or the phase distribution caused by the projection optics) of the projection optics. The projection optics model 1510 can represent the optical characteristics of the projection optics, including aberration, distortion, one or more refractive indexes, one or more physical sizes, one or more physical dimensions, etc.

The patterning device/design layout model module 1520 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1520 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1530 can be simulated from the source model 1500, the projection optics model 1510 and the patterning device/design layout model 1520. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1550 can be simulated from the aerial image 1530 using a resist model 1540. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1510.

In general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1560. The post-pattern transfer process model 1560 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes the known physics and chemistry of the overall process, and each of the model parameters desirably corresponds to a distinct physical or chemical effect. The model formulation thus sets an upper bound on how well the model can be used to simulate the overall manufacturing process.

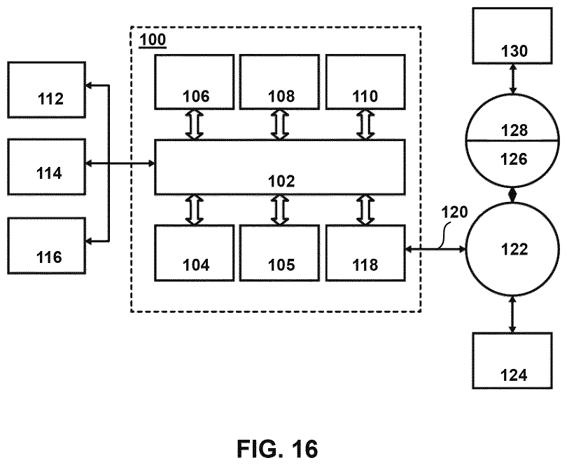

FIG. 16 is a block diagram that illustrates a computer system 100 that can assist in implementing the methods, flows or the system(s) disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random-access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide all or part of a method described herein, for example. The received code may be executed by processor 104 as it is received, and/or stored in storage device 110, or other non-volatile storage for later execution. In this manner, computer system 100 may obtain application code in the form of a carrier wave.

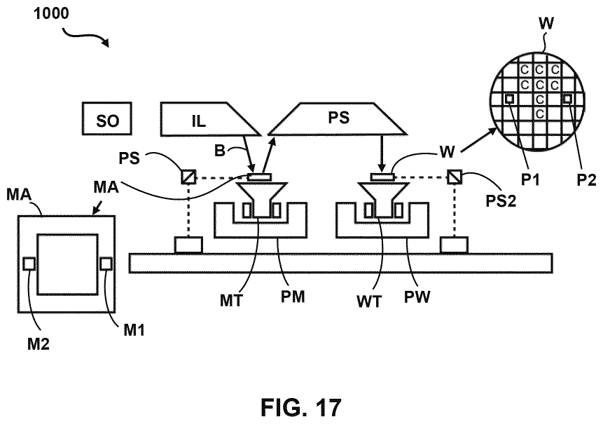

FIG. 17 schematically depicts an exemplary lithographic projection apparatus in conjunction with the techniques described herein can be utilized. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 17 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

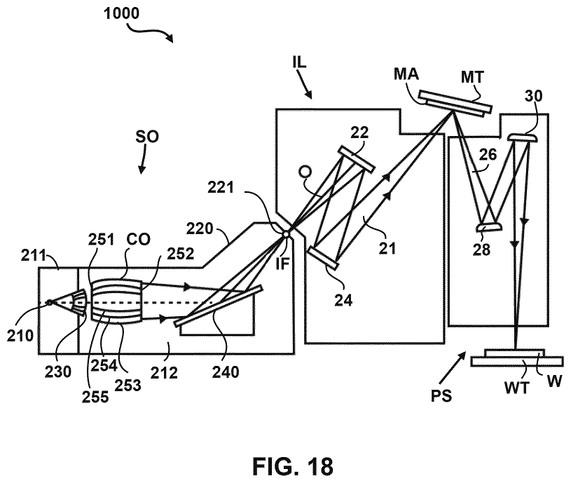

FIG. 18 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 18.

Collector optic CO, as illustrated in FIG. 18, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

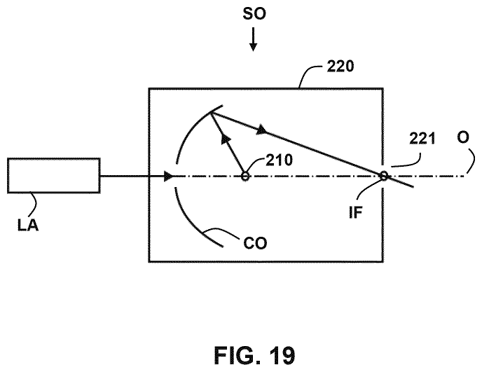

Alternatively, the source collector module SO may be part of an LPP radiation system as shown in FIG. 19. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The embodiments may further be described using the following clauses:

1. A method for grouping image patterns to determine wafer behavior in a patterning process with a trained machine learning model, the method comprising:

converting, based on the trained machine learning model, one or more patterning process images comprising the image patterns into feature vectors, the feature vectors corresponding to the image patterns; and

grouping, based on the trained machine learning model, feature vectors with features indicative of image patterns that cause matching wafer behavior in the patterning process.

2. The method of clause 1, wherein the method for grouping image patterns to determine wafer behavior is a method for grouping image patterns to identify potential wafer defects in the patterning process, the method further comprising: grouping, based on the trained machine learning model, feature vectors with features indicative of image patterns that cause matching wafer defect behavior in the patterning process.
3. The method of clause 1 or 2, wherein the one or more patterning process images comprise aerial images and/or resist images.
4. The method of any of clauses 1-3, further comprising using the grouped feature vectors to facilitate detection of potential patterning defects on a wafer during a lithography manufacturability check (LMC).
5. The method of any of clauses 1-4, wherein the trained machine learning model comprises a first trained machine learning model and a second trained machine learning model, wherein converting the one or more patterning process images comprising the image patterns into feature vectors is based on the first trained machine learning model, and wherein grouping feature vectors with features indicative of image patterns that cause matching wafer or wafer defect behavior is based on the second trained machine learning model.
6. The method of clause 5, wherein the first machine learning model is an image encoder trained to:

extract features from aerial images and/or resist images indicative of:
short range aerial and/or resist image pattern configurations; and
long range pattern structures that influence the wafer or wafer defect behavior; and

encode the extracted features into the feature vectors.

7. The method of clause 6, wherein the first machine learning model comprises a loss function.
8. The method of clause 6 or 7, wherein grouping the feature vectors with features indicative of image patterns that cause matching wafer or wafer defect behavior based on the second machine learning model comprises:

grouping the feature vectors into first groups based on the features indicative of the short-range aerial and/or resist image pattern configurations, and

grouping the feature vectors into second groups based on the first groups and the long-range pattern structures that influence the wafer or wafer defect behavior,

such that the second groups comprise the groups of feature vectors with the features indicative of image patterns that cause the matching wafer or wafer defect behavior in the patterning process.

9. The method of any of clauses 5-8, further comprising training the first machine learning model with simulated aerial images and/or resist images.
10. The method of clause 9, further comprising iteratively re-training the first machine learning model based on output from the first machine learning model and additional simulated aerial and/or resist images.
11. The method of clause 10, wherein the first machine learning model comprises the loss function, and iteratively re-training the first machine learning model based on the output from the first machine learning model and the additional simulated aerial and/or resist images comprises adjusting the loss function.
12. The method of any of clauses 5-11, further comprising training the second machine learning model with labeled wafer defects from a wafer verification process.
13. The method of clause 12, wherein a given labeled wafer defect includes information related to: short range aerial and/or resist image pattern configurations associated with the given labeled wafer defect, long range pattern structures associated with the given labeled wafer defect, behavior of the given labeled wafer defect in the patterning process, coordinates of a location of the given labeled wafer defect and a critical dimension at that location, an indication of whether the given labeled wafer defect is a real defect or not, and/or information related to an exposure of an image of the given labeled wafer defect at the location.
14. The method of clause 13, wherein the information related to the short-range aerial and/or resist image pattern configurations associated with the given labeled wafer defect, and the long-range pattern structures associated with the given labeled wafer defect, are related to a probability of whether the given labeled wafer defect is real or not.
15. The method of clause 14, further comprising iteratively re-training the second machine learning model based on output from the second machine learning model, the given labeled wafer defect, and additional labeled wafer defects from the wafer verification process.
16. The method of any of clauses 1-15, wherein the feature vectors describe the image patterns and include features related to LMC model terms and/or imaging conditions for the one or more patterning process images.
17. The method of clause 16, wherein the method comprises the grouping of the feature vectors into first groups based on the features indicative of the short-range aerial and/or resist image pattern configurations, and

wherein the features indicative of the short-range aerial and/or resist image pattern configurations include the features related to LMC model terms and/or imaging conditions for the one or more patterning process images.

18. The method of any of clauses 1-17, wherein the method is used during an optical proximity correction (OPC) portion of the patterning process.
19. The method of clause 18, further comprising identifying groups of potential wafer defects that have matching wafer defect behavior in the patterning process based on the grouping of the feature vectors with the features indicative of image patterns that cause the matching wafer defect behavior in the patterning process.
20. The method of clause 19, further comprising adjusting a mask layout design of a mask of the patterning process based on the groups of potential wafer defects that have the matching wafer defect behavior in the patterning process.
21. The method of any of clauses 1-20, wherein the method is used to generate a gauge line/defect candidate list to enhance accuracy and efficiency of wafer verification.
22. The method of any of clauses 1-21, further comprising predicting, based on the trained machine learning model, a ranking indicator to indicate a relative severity of individual potential wafer defects, the ranking indicator being a measure of how likely a potential wafer defect is to transform into one or more physical wafer defects.
23. A computer program product comprising a non-transitory computer readable medium having instructions recorded thereon, the instructions when executed by a computer implementing the method of any of clauses 1-22.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

In addition, the term “projection optics” as used herein should be broadly interpreted (in addition to what was described above) as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

The descriptions above are intended to be illustrative, not limiting. Thus, it will be apparent to one skilled in the art that modifications may be made as described without departing from the scope of the claims set out below.

1. A method comprising:
converting, based on a trained machine learning model, one or more patterning process images comprising image patterns into feature vectors, the feature vectors corresponding to the image patterns; and
grouping, by a hardware computer system and based on the trained machine learning model, feature vectors with features indicative of image patterns that cause matching wafer behavior in a patterning process.

2. The method of claim 1, wherein the method is for grouping image patterns to identify potential wafer defects in the patterning process, and the grouping comprises grouping, based on the trained machine learning model, feature vectors with features indicative of image patterns that cause matching wafer defect behavior in the patterning process.

3. The method of claim 1, wherein the one or more patterning process images comprise aerial images and/or resist images.

4. The method of claim 1, further comprising using the grouped feature vectors to facilitate detection of potential patterning defects on a wafer during a lithography manufacturability check (LMC).

5. The method of claim 1, wherein the trained machine learning model comprises a first trained machine learning model and a second trained machine learning model, wherein converting the one or more patterning process images comprising the image patterns into feature vectors is based on the first trained machine learning model, and wherein grouping feature vectors with features indicative of image patterns that cause matching wafer behavior is based on the second trained machine learning model.

6. The method of claim 5, wherein the first machine learning model is an image encoder trained to:
extract features from aerial images and/or resist images indicative of:
short range aerial and/or resist image pattern configurations; and
long range pattern structures that influence the wafer behavior; and
encode the extracted features into the feature vectors, and/or
wherein the first machine learning model comprises a loss function.

7. The method of claim 6, wherein grouping the feature vectors with features indicative of image patterns that cause matching wafer behavior based on the second machine learning model comprises:
grouping the feature vectors into first groups based on the features indicative of the short-range aerial and/or resist image pattern configurations, and
grouping the feature vectors into second groups based on the first groups and the long-range pattern structures that influence the wafer behavior,
such that the second groups comprise the groups of feature vectors with the features indicative of image patterns that cause the matching wafer behavior in the patterning process.

8. The method of claim 5, further comprising training the first machine learning model with simulated aerial images and/or resist images.

9. The method of claim 8, further comprising iteratively re-training the first machine learning model based on output from the first machine learning model and additional simulated aerial and/or resist images, and/or
wherein the first machine learning model comprises a loss function, and further comprising iteratively re-training the first machine learning model based on the output from the first machine learning model and the additional simulated aerial and/or resist images including adjusting the loss function.

10. The method of claim 5, further comprising training the second machine learning model with labeled wafer defects from a wafer verification process.

11. The method of claim 10, wherein a given labeled wafer defect includes information related to: short range aerial and/or resist image pattern configurations associated with the given labeled wafer defect and/or long range pattern structures associated with the given labeled wafer defect, and wherein the information related to the short-range aerial and/or resist image pattern configurations associated with the given labeled wafer defect, and/or the long-range pattern structures associated with the given labeled wafer defect, are related to a probability of whether the given labeled wafer defect is real or not, and/or
further comprising iteratively re-training the second machine learning model based on output from the second machine learning model, the given labeled wafer defect, and additional labeled wafer defects from the wafer verification process.

12. The method of claim 1, wherein the feature vectors describe the image patterns and include features related to lithography manufacturability check (LMC) model terms and/or imaging conditions for the one or more patterning process images.

13. The method of claim 12, comprising grouping of the feature vectors into groups based on the features indicative of short-range aerial and/or resist image pattern configurations, and
wherein the features indicative of the short-range aerial and/or resist image pattern configurations include the features related to LMC model terms and/or imaging conditions for the one or more patterning process images.

14. The method of claim 1, further comprising training the machine learning model configured to predict wafer behavior by grouping feature vectors with features indicative of image patterns that cause matching wafer behavior in the patterning process.

15. A computer program product comprising a non-transitory computer readable medium having instructions therein, the instructions, when executed by a computer system, configured to cause the computer system to at least:
convert, based on a trained machine learning model, one or more patterning process images comprising image patterns into feature vectors, the feature vectors corresponding to the image patterns; and
group, based on the trained machine learning model, feature vectors with features indicative of image patterns that cause matching wafer behavior in a patterning process.

16. The computer program product of claim 15, configured group image patterns to identify potential wafer defects in the patterning process, and the instructions configured to cause the computer system to group the feature vectors are configured to group, based on the trained machine learning model, feature vectors with features indicative of image patterns that cause matching wafer defect behavior in the patterning process.

17. The computer program product of claim 15, wherein the one or more patterning process images comprise aerial images and/or resist images.

18. The computer program product of claim 15, wherein the instructions are further configured to cause the computer system to use the grouped feature vectors to facilitate detection of potential patterning defects on a wafer during a lithography manufacturability check (LMC).

19. The computer program product of claim 15, wherein the trained machine learning model comprises a first trained machine learning model and a second trained machine learning model, wherein the instructions configured to cause the computer system to convert the one or more patterning process images are configured to do so based on the first trained machine learning model, and wherein the instructions configured to cause the computer system to group the feature vectors are configured to do so based on the second trained machine learning model.

20. The computer program product of claim 15, wherein the feature vectors describe the image patterns and include features related to model terms and/or imaging conditions for the one or more patterning process images.
